(19) United States
(12) Patent Application Publication
(10) Pub. No.: US 2026/0123505 A1
(43) Pub. Date: Apr. 30, 2026

(54) METHOD FOR MANUFACTURING SEMICONDUCTOR DEVICE, AND WIRING BOARD

(71) Applicant: Resonac Corporation, Minato-ku, Tokyo (JP)

(72) Inventors: Keiichi HATAKEYAMA, Tokyo (JP); Masaaki TAKEKOSHI, Tokyo (JP); Goki TOSHIMA, Tokyo (JP); Seiji KAI, Tokyo (JP)

(21) Appl. No.: 19/160,858

(22) PCT Filed: Apr. 30, 2024
(86) PCT No.: PCT/JP2024/016673

§ 371 Date: Aug. 29, 2025

(51) Int. Cl. H10W 72/30; H10B 80/00; H10D 80/30; H10W 74/01; H10W 90/00; H10W 90/10

(52) U.S. Cl. CPC H10W 72/354; H10W 74/01; H10W 90/734; H10B 80/00; H10D 80/30; H10W 90/10

(57) ABSTRACT

Copper posts 22 are provided on a carrier substrate 20, and a semiconductor die 40 serving as a bridge die is attached between the copper posts 22. The semiconductor die 40 is attached by the resin layer 43 covering the terminal electrodes 42 such that the terminal electrodes 42 face the carrier substrate 20. The resin layer 43 is cured to form an encapsulant layer 23. A wiring layer 24 is formed on one side of the encapsulant layer 23, and a wiring layer 28 is formed on the other surface. Active dies 50 and 55 are attached to an interposer P. According to this method, a bridge die is attached in a face-down manner. Thus, reliable attachment can be realized. Since an expensive active die is attached last, manufacturing cost can be reduced. For the resin layer 43, an NCF or a DAF is preferably used.

### TECHNICAL FIELD

The present disclosure relates to a method for manufacturing a semiconductor device, and a wiring board.

### BACKGROUND ART

In recent years, with rapid enhancement of functions of electronic devices represented by AI/HPC and the like, semiconductor packages have been rapidly increased in size and density. Not only a packaging structure thereof becomes to have denser surface mounting, but the packaging structure and a packaging process are also becoming more complicated and diversified, with an inorganic (silicon) or organic interposer (Bridge die/RDL) technology, 2.xD mounting using the same, and a 3D mounting (HBM/Chiplet) technology utilizing TSV. For example, with “Packaging Solution Center” as a main base, RESONAC CORPORATION is conducting technological development of a next generation semiconductor packaging process in the eye line of customers (semiconductor manufacturers) by combining a mounting process and materials.

As a technology in such a semiconductor packaging field, Patent Literature 1 discloses a method for manufacturing a semiconductor device in which a semiconductor die is mounted face-up on a carrier to encapsulate the semiconductor die, a wiring layer is formed on an encapsulating layer, and another semiconductor die is mounted on the wiring layer. Patent Literature 2 discloses another method for manufacturing a semiconductor device.

### CITATION LIST

### Patent Literature

Patent Literature 1: US 2021/0098421 A
Patent Literature 2: US 2022/0093526 A

### SUMMARY OF INVENTION

### Technical Problem

In the method for manufacturing a semiconductor device described in Patent Literature 1, in order to mount the semiconductor die on a support, it is conceivable to mount the semiconductor die on the support as it is in a face-up manner by sucking and lifting a terminal electrode side of the semiconductor die with a collet. In this case, an outer periphery of the semiconductor die is sucked by a collet so as to avoid an internal region where terminal electrodes are provided. However, when attachment is performed in such a suction state, attachment of the semiconductor die may not be reliably performed.

An object of the present disclosure is to provide a method for manufacturing a semiconductor device capable of reliably attaching a semiconductor member (semiconductor die).

### Solution to Problem

[1] The present disclosure relates to, as one aspect, a method for manufacturing a semiconductor device. This method for manufacturing a semiconductor device includes: providing a conductive post member having a first end and a second end on the opposite side on a first support, the first end being located on a side of the first support; attaching a semiconductor member including a semiconductor substrate having a first surface and a second surface on the opposite side, a terminal electrode provided on the first surface side of the semiconductor substrate, and a resin layer provided on the first surface side so as to cover the terminal electrode, to the first support such that the first surface faces the first support; forming a first encapsulant layer encapsulating the post member and the semiconductor member on the first support; forming a first wiring layer electrically connected to at least the post member on the first encapsulant layer; separating the first support from the first encapsulant layer; grinding at least the resin layer so as to expose a tip of the terminal electrode; and forming a second wiring layer electrically connected to at least one of the terminal electrode and the post member on the first encapsulant layer where the terminal electrode is exposed.

In this method for manufacturing a semiconductor device, the semiconductor member is attached to the first support such that the first surface on which the terminal electrode is provided faces the support. That is, the semiconductor member is attached in a face-down manner. Therefore, when the semiconductor member is sucked by a collet or the like and bonded, it is not necessary to suck the terminal electrode side, and the semiconductor member can be reliably attached. Note that, when the semiconductor member is picked up before bonding, the terminal electrode side may be once sucked by a collet (and then turned over to perform bonding), and in this case, since the terminal electrode is covered with the resin layer, the outer periphery does not need to be sucked by the collet, and the semiconductor member can be reliably picked up.

Furthermore, in this method for manufacturing a semiconductor device, the semiconductor chip connected to the semiconductor member can be attached at the end of the process (for example, after forming the first wiring layer and the second wiring layer). Thus, when a defect occurs at an intermediate stage, it is possible not to attach a semiconductor chip which is an expensive active die. As a result, the overall manufacturing cost can be reduced.
[2] The method for manufacturing a semiconductor device according to [1] preferably further includes curing the resin layer containing a curable resin composition after attaching the semiconductor member to the first support and before forming the first encapsulant layer. In this case, it is possible to prevent the position of the semiconductor member from being displaced when the first encapsulant layer is formed (encapsulated).
[3] In the method for manufacturing a semiconductor device according to [1] or [2], the resin layer when the semiconductor member is attached to the first support may be a semi-cured or uncured curable resin composition. In this case, the semiconductor member can be reliably attached to a predetermined position on the first support.
[4] In the method for manufacturing a semiconductor device according to any one of [1] to [3], the resin layer preferably has a transmittance of 30% or more with respect to visible light. In this case, the position of the terminal electrode of the semiconductor member is confirmed before performing attachment, and the semiconductor member can be attached to a predetermined position on the first support with high accuracy.
[5] In the method for manufacturing a semiconductor device according to any one of [1] to [4], in the attaching the semiconductor member, it is preferable that a position of the terminal electrode is determined through the resin layer, and the semiconductor member is attached to a predetermined position of the first support based on a result of the determination. In this case, the position of the terminal electrode of the semiconductor member is directly or indirectly confirmed, and the semiconductor member can be attached to a predetermined position on the first support with high accuracy.
[6] In the method for manufacturing a semiconductor device according to any one of [1] to [5], the resin layer may contain inorganic fillers. In this case, the hardness (such as elastic modulus) of the resin layer can be improved, and bending or cracking of the semiconductor member can be prevented. Furthermore, when the inorganic fillers are contained, warpage of the semiconductor member including the resin layer can be decreased.
[7] In the method for manufacturing a semiconductor device according to [6], a content of the inorganic fillers may be 30 mass % or more based on a total solid content contained in the resin layer. In this case, the warpage of the semiconductor member can be more reliably decreased.
[8] In the method for manufacturing a semiconductor device according to [6] or [7], an average particle diameter of the inorganic fillers may be 20 μm or less. In this case, even when each terminal electrode of the semiconductor member and a pitch thereof are miniaturized, a resin and fillers can be made to enter (fill) between the respective terminal electrodes, and the terminal electrodes can be reliably covered with the resin layer. Furthermore, warping of the cured resin layer can be decreased.
[9] In the method for manufacturing a semiconductor device according to any one of [1] to [8], an elastic modulus at room temperature of the resin layer when being cured may be 10 MPa or more. In this case, bending and cracking of the semiconductor member can be further prevented. Furthermore, when the cured resin layer is polished to expose the terminal electrodes, a polishing operation can be easily performed. The elastic modulus referred to here means Young's modulus. The room temperature means 25° C. Note that, regarding the cured resin layer, a case where the resin layer is not completely cured is also included, and it is sufficient that the resin layer is hard to such an extent that the resin layer can be polished in the polishing operation.
[10] In the method for manufacturing a semiconductor device according to any one of [1] to [9], the resin layer may be formed by bonding a non-conductive adhesive film (NCF) or a die attach film (DAF). In this case, the resin layer is preferably formed by bonding an NCF.
[11] In the method for manufacturing a semiconductor device according to any one of [1] to [10], a thickness of the resin layer may be between 100% and 150% with respect to a height of the terminal electrode. In this case, since the thickness of the resin layer is substantially equal to the height of the terminal electrode, the semiconductor member can be lifted and attached more reliably.
[12] In the method for manufacturing a semiconductor device according to any one of [1] to [11], the resin layer may be formed by bonding a resin film, and a thickness of the resin film before bonding may be between 75% to 150% with respect to the height of the terminal electrode. In this case, when the resin film is bonded, since the thickness of the resin layer is substantially equal to the height of the terminal electrode, the semiconductor member can be lifted and attached more reliably.
[13] The method for manufacturing a semiconductor device according to any one of [1] to [12] may further include grinding the first encapsulant layer such that the second end of the post member is exposed after forming the first encapsulant layer and before forming the first wiring layer. In this case, the first wiring layer connected to the post member can be formed more reliably.
[14] The method for manufacturing a semiconductor device according to any one of [1] to [13] may further include providing a second support on the first wiring layer after forming the first wiring layer. The first support may be separated from the first encapsulant layer after providing the second support. In this case, since various manufacturing processes can be performed in a state where the first encapsulant layer is supported by any one of the supports, a semiconductor device using a thin first encapsulant layer can be manufactured. Furthermore, even when the first encapsulant layer is thin, warpage or cracking can be prevented.
[15] The method for manufacturing a semiconductor device according to [14] may further include providing a connection bump on a surface of the first wiring layer on a side opposite to the first encapsulant layer. The providing a connection bump may be performed before providing the second support on the first wiring layer or after separating the second support from the first wiring layer. When the connection bump is formed before providing the second support on the first wiring layer, since an active die such as a logic die can be attached in the last process, it is not necessary to attach an expensive active die when there is a defect in a wiring board, and manufacturing cost can be reduced. Furthermore, when the connection bump is formed after separating the second support from the first wiring layer, since many processes can be performed on a wiring board in a state where the connection bump is not present, various processes such as formation of the second wiring layer can be easily performed, and the manufacturing efficiency can be improved.
[16] In the method for manufacturing a semiconductor device according to any one of [1] to [15], the semiconductor member may include a fine wiring layer between the first surface of the semiconductor substrate and the terminal electrode. In this case, a fine circuit in the semiconductor substrate and the terminal electrode can be reliably connected.
[17] In the method for manufacturing a semiconductor device according to any one of [1] to [16], the semiconductor member may include an internal electrode extending in a thickness direction of the semiconductor substrate. A first end of the internal electrode may be connected to the second wiring layer via the terminal electrode, and a second end of the internal electrode may be connected to the first wiring layer. In this case, a through electrode such as a through silicon via (TSV) can be provided on the semiconductor substrate, and the degree of freedom in designing the wiring can be improved. Furthermore, miniaturization of wiring can be enhanced.
[18] The method for manufacturing a semiconductor device according to any one of [1] to [17] preferably further includes attaching at least one semiconductor chip to a surface of the second wiring layer on a side opposite to the first encapsulant layer.
[19] In the method for manufacturing a semiconductor device according to [18], in the attaching a semiconductor chip, a first semiconductor chip and a second semiconductor chip as the at least one semiconductor chip are preferably attached to the second wiring layer. The first semiconductor chip and the second semiconductor chip are preferably electrically connected by the semiconductor member. In this case, the semiconductor member can be used as a so-called bridge die.
[20] The method for manufacturing a semiconductor device according to [18] or [19] may further include forming a second encapsulant layer encapsulating the at least one semiconductor chip. In this case, the semiconductor chip is reliably protected by the encapsulant layer.
[21] In the method for manufacturing a semiconductor device according to any one of [1] to [20], it is preferable that at least one of a first connection point between the post member and the first wiring layer and a second connection point between the post member and the second wiring layer is connected in a solderless manner. In this case, it is not necessary to consider diffusion of solder or the like, so that the design of the semiconductor device can be simplified accordingly.
[22] In the method for manufacturing a semiconductor device according to any one of [1] to [21], the post member may be provided in a substrate having a first surface and a second surface on the opposite side. In the providing a post member, the post member may be provided on the first support by attaching a connection member to the first support such that the first surface faces the support. The connection member includes the post member, the substrate, another terminal electrode provided on the first surface side of the substrate, and another resin layer provided on the first surface side of the substrate so as to cover another terminal electrode. In this case, the providing a post member can be simplified. Furthermore, the semiconductor member and the connection member can be attached in parallel, and the manufacturing efficiency can be improved.
[23] In the method for manufacturing a semiconductor device according to [22], in the forming a first encapsulant layer, the connection member may be encapsulated together with the semiconductor member. In the grinding, the resin layer and another resin layer may be ground such that another terminal electrode is exposed together with the terminal electrode. In the forming a second wiring layer, the second wiring layer may be formed such that the second wiring layer is electrically connected to each of the terminal electrode and another terminal electrode. In this case, even in the case of using the connection member, a semiconductor device can be manufactured similarly to the case of directly forming a post member.
[24] The method for manufacturing a semiconductor device according to any one of [22] or [23] may further include grinding a part of the semiconductor substrate and a part of the substrate together with the first encapsulant layer such that the second end of the post member is exposed after forming the first encapsulant layer and before forming the first wiring layer. In this case, even in the case of using the connection member, a semiconductor device can be manufactured similarly to the case of directly forming a post member.
[25] The present disclosure relates to, as another aspect, a wiring board being used for manufacturing a semiconductor device. This wiring board includes a semiconductor member, a conductive post member having a first end and a second end on the opposite side and provided adjacent to the semiconductor member, a first encapsulant layer encapsulating the semiconductor member and the post member, a first wiring layer provided on the first encapsulant layer and electrically connected to at least the post member, and a second wiring layer provided on a surface of the first encapsulant layer on a side opposite to the first wiring layer and electrically connected to at least one of the terminal electrode and the post member. The semiconductor member of this wiring board includes a semiconductor substrate having a first surface and a second surface on the opposite side, a terminal electrode provided on the first surface side of the semiconductor substrate, and a resin layer provided on the first surface side so as to expose a tip of the terminal electrode and cover another portion of the terminal electrode. Such a wiring board can be used as an interposer for manufacturing a semiconductor device by mounting a semiconductor chip.
[26] The present disclosure relates to, as still another aspect, a method for manufacturing a semiconductor device. This manufacturing method includes providing the wiring board according to [25] and attaching a first semiconductor chip and a second semiconductor chip onto the second wiring layer of the wiring board. In the attaching, the first semiconductor chip is electrically connected to the second semiconductor chip by the semiconductor member. In this case, a semiconductor device in which the semiconductor member functions as a bridge die can be easily manufactured.
[27] In the method for manufacturing a semiconductor device according to [26], the first semiconductor chip may include a logic chip, and the second semiconductor chip may include a memory chip. In this case, the logic chip can be easily connected to the memory chip through a bridge die.

### Advantageous Effects of Invention

According to the present disclosure, it is possible to provide a method for manufacturing a semiconductor device capable of reliably attaching a semiconductor member.

### BRIEF DESCRIPTION OF DRAWINGS

FIG. 1 is a cross-sectional view illustrating an example of a cross-sectional configuration of a semiconductor device according to a first embodiment.

FIG. 2 (a) to (d) in FIG. 2 are cross-sectional views illustrating a method for manufacturing the semiconductor device illustrated in FIG. 1.

FIG. 3 (a) and (b) in FIG. 3 are enlarged cross-sectional views illustrating a semiconductor member to be attached in FIG. 2 (c).

FIG. 4 (a) to (d) in FIG. 4 are cross-sectional views illustrating the method for manufacturing the semiconductor device illustrated in FIG. 1, and illustrate steps performed after the step illustrated in FIG. 2 (d).

FIG. 5 (a) to (c) in FIG. 5 are cross-sectional views illustrating the method for manufacturing the semiconductor device illustrated in FIG. 1, and illustrate steps performed after the step illustrated in FIG. 4 (d).

FIG. 6 (a) to (c) in FIG. 6 are cross-sectional views illustrating the method for manufacturing the semiconductor device illustrated in FIG. 1, and illustrate steps performed after the step illustrated in FIG. 5 (c).

FIG. 7 is a cross-sectional view illustrating an example of a cross-sectional configuration of a semiconductor device according to a second embodiment.

FIG. 8 (a) to (d) in FIG. 8 are cross-sectional views illustrating a method for manufacturing the semiconductor device illustrated in FIG. 7.

FIG. 9 (a) to (c) in FIG. 9 are cross-sectional views illustrating the method for manufacturing the semiconductor device illustrated in FIG. 7, and illustrate steps performed after the step illustrated in FIG. 8 (d).

FIG. 10 (a) to (c) in FIG. 10 are cross-sectional views illustrating the method for manufacturing the semiconductor device illustrated in FIG. 7, and illustrate steps performed after the step illustrated in FIG. 9 (c).

FIG. 11 (a) to (c) in FIG. 11 are cross-sectional views illustrating the method for manufacturing the semiconductor device illustrated in FIG. 7, and illustrate steps performed after the step illustrated in FIG. 10 (c).

### DESCRIPTION OF EMBODIMENTS

Hereinafter, embodiments according to the present invention will be described in detail with reference to the drawings. In the following description, the same or corresponding portions are denoted by the same reference numerals, and redundant description is omitted. Further, unless otherwise specified, a positional relationship such as up, down, left, and right is based on a positional relationship illustrated in the drawings. Furthermore, dimensional ratios in the drawings are not limited to the illustrated ratios.

In the present specification, the term “layer” includes a structure having a shape partially formed in addition to a structure having a shape formed on the entire surface when observed as a plan view. In the present specification, the term “step” includes not only an independent step but also a step that cannot be clearly distinguished from other steps as long as an intended action of the step is achieved. Note that, in the present description, “(meth)acryl” means acryl or methacryl corresponding thereto. Furthermore, when a plurality of substances corresponding to each component are present in the composition, the content of each component in the composition means the total amount of the plurality of substances present in the composition unless otherwise specified.

In the present description, a numerical range expressed by using “to” indicates a range including numerical values described before and after “to” as a minimum value and a maximum value, respectively. In numerical ranges described in stages in the present specification, an upper limit value or a lower limit value of a numerical range in a certain stage may be replaced with an upper limit value or a lower limit value of a numerical range in another stage. In a numerical range written in the present description, the upper limit value or the lower limit value of the numerical range may be replaced with a value shown in Examples.

### First Embodiment

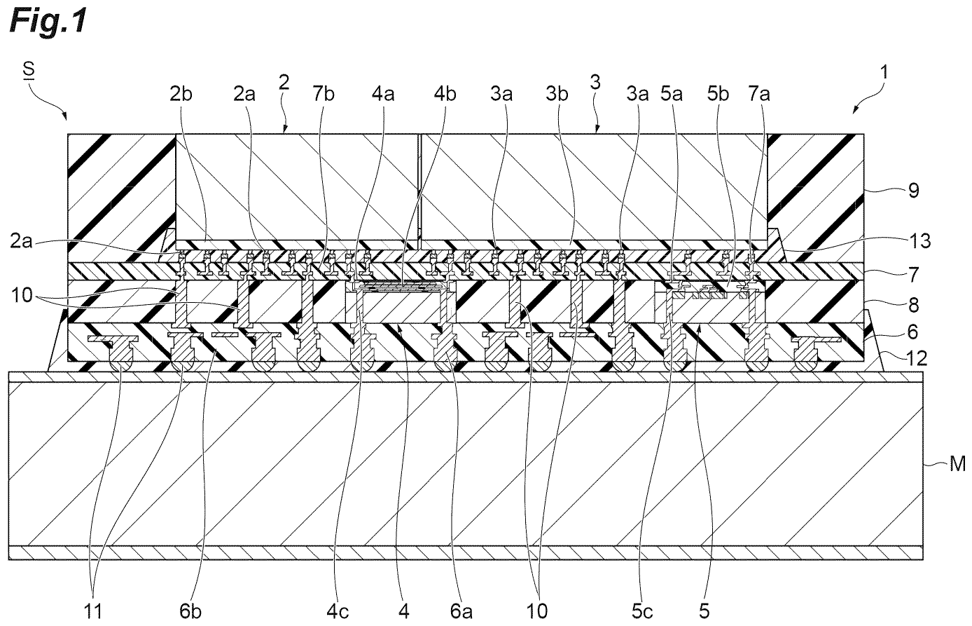

FIG. 1 is a view illustrating an example of a semiconductor device manufactured by a manufacturing method according to a first embodiment. As illustrated in FIG. 1, a semiconductor device 1 includes semiconductor dies 2 and 3, semiconductor dies 4 and 5, wiring layers 6 and 7, encapsulant layers 8 and 9, connection electrodes 10, connection bumps 11, and underfills 12 and 13. Such a semiconductor device 1 is mounted on a substrate M. The substrate M is, for example, a motherboard. A structure S in which the semiconductor device 1 is further mounted on the substrate M may be referred to as a semiconductor device. In the semiconductor device 1, the wiring layer 6, the encapsulant layer 8 encapsulating the semiconductor dies 4 and 5 and the connection electrodes 10, the wiring layer 7 electrically connected to the semiconductor dies 4 and 5 and the connection electrodes 10, and the encapsulant layer 9 encapsulating the semiconductor dies 2 and 3 are sequentially laminated on the substrate M.

The semiconductor dies 2 and 3 (first semiconductor chip, second semiconductor chip) are, for example, semiconductor chips such as an LSI chip (logic chip), a CMOS sensor, and a memory chip, and may be so-called active dies. Each of the semiconductor dies 2 and 3 includes terminal electrodes 2a and 3a and fine wiring layers 2b and 3b provided on the terminal electrodes 2a and 3a side. In the semiconductor device 1, the semiconductor dies 2 and 3 are mounted such that the terminal electrodes 2a and 3a face the semiconductor dies 4 and 5 and the wiring layer 7. An underfill material is introduced into a connection region of the terminal electrodes 2a and 3a and cured to form the underfill 13. Furthermore, the semiconductor dies 2 and 3 are encapsulated with an encapsulant constituting the encapsulant layer 9, and each surface is exposed to the outside.

The semiconductor dies 4 and 5 (semiconductor members) are, for example, bridge dies or silicon capacitors, and may be so-called passive dies. The semiconductor dies 4 and 5 may be active dies. The semiconductor dies 4 and 5 are extremely thin semiconductor dies, have, for example, a thickness of 100 μm or less, and may have a thickness of 50 um or less. Each of the semiconductor dies 4 and 5 includes terminal electrodes 4a and 5a and fine wiring layers 4b and 5b provided on the terminal electrodes 4a and 5a side. The terminal electrodes 4a and 5a of the semiconductor dies 4 and 5 and a pitch thereof are also miniaturized, the diameter of each of the terminal electrode 4a and the terminal electrode 5a is, for example, 10 μm to 50 μm, and the height of each of the terminal electrodes 4a and 5a is, for example, 20 μm to 50 μm. Furthermore, a terminal pitch (separation distance) between the terminal electrodes 4a and a terminal pitch (separation distance) between the terminal electrodes 5a are, for example, 5 μm to 20 μm. However, the size and pitch of the terminal electrodes 4a and 5a are not limited to those described above.

In the semiconductor device 1, the semiconductor dies 4 and 5 are installed such that the terminal electrodes 4a and 5a face the semiconductor dies 2 and 3. As an example, the semiconductor die 4 is a bridge die, and connects the semiconductor die 2 and the semiconductor die 3 to each other via a wiring portion 7a of the wiring layer 7 (second wiring layer). The semiconductor die 5 is connected to the semiconductor die 3 via the wiring portion 7a of the wiring layer 7, and is not connected to the semiconductor die 2. When the semiconductor dies 4 and 5 further include through electrodes 4c and 5c, the semiconductor dies 4 and 5 may connect the semiconductor dies 2 and 3 to a wiring portion 6a of the wiring layer 6 (first wiring layer) via the through electrodes 4c and 5c.

The wiring layers 6 and 7 are redistribution layers, and include the wiring portions 6a and 7a and insulating portions 6b and 7b respectively covering the wiring portions 6a and 7a. The wiring layer 6 and the wiring layer 7 may have a structure with the same wiring pitch and wiring width, but the wiring pitch and the wiring width of the wiring layer 7 are preferably narrower than the wiring pitch and the wiring width of the wiring layer 6. The wiring portion 6a of the wiring layer 6 is connected to the connection bump 11. The connection bump 11 is, for example, a solder bump. An underfill material is introduced into a connection region of the connection bumps 11 and cured to form the underfill 12.

The encapsulant layers 8 and 9 are layers that encapsulate a semiconductor die with an encapsulant, and are encapsulated with an encapsulant containing, for example, an epoxy resin or the like. The encapsulant layer 8 encapsulates the semiconductor dies 4 and 5. The encapsulant layer 9 encapsulates the semiconductor dies 2 and 3.

The connection electrode 10 is a conductive post member connecting the wiring layers 6 and 7 (wiring portions 6a and 7a), and is a so-called post or pillar. The connection electrode 10 is formed of, for example, copper or the like. The connection electrode 10 is provided adjacent to the semiconductor dies 4 and 5. The height of the connection electrode 10 is substantially the same as the thickness of the semiconductor dies 4 and 5. The diameter of the connection electrode 10 is, for example, 10 μm to 50 μm. The connection electrode 10 is encapsulated with an encapsulant together with the semiconductor dies 4 and 5, and is located in the encapsulant layers 8 and 9. The semiconductor dies 4 and 5 are disposed between the connection electrodes 10.

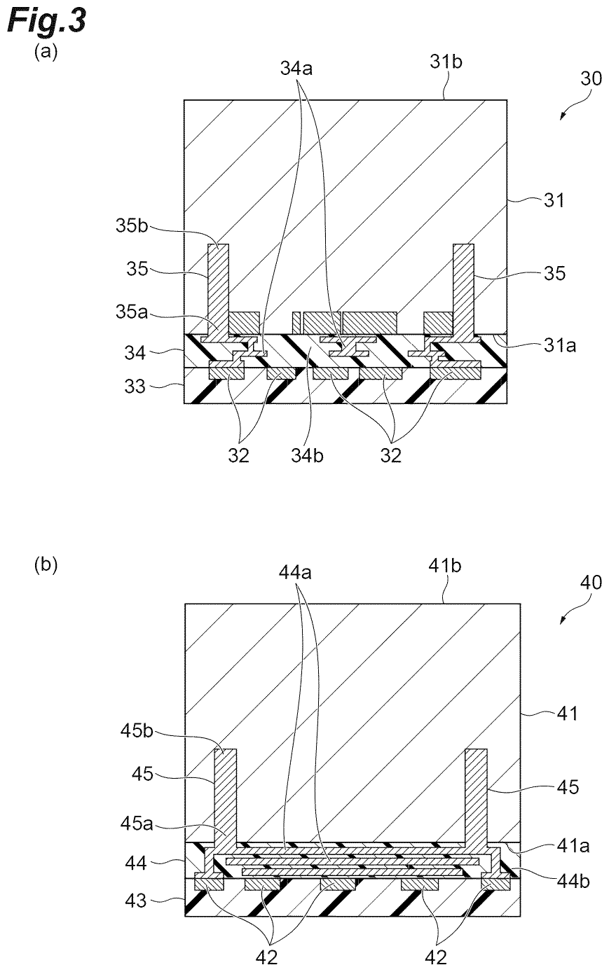

In the semiconductor device 1, the semiconductor dies 4 and 5 are provided in the encapsulant layer 8 in a face-up state. The semiconductor dies 4 and 5 are provided with resin layers (see resin layers 33 and 43 in FIG. 3) formed so as to cover the plurality of terminal electrodes 4a and 5a. Tips of the plurality of terminal electrodes 4a and 5a are exposed to the outside from the resin layer and connected to the wiring portion 7a, while other portions of the plurality of terminal electrodes 4a and 5a are covered with the resin layer. Such a resin layer is composed of a resin film containing a thermosetting adhesive such as a non-conductive film (NCF) or a die attach film (DAF), or a liquid thermosetting adhesive, and is a cured resin layer obtained by curing any of the adhesive layers, which will be described in detail later. That is, a material constituting the resin layer is in a semi-cured (B-stage) state and then in a completely cured (C-stage) state by the subsequent curing treatment. The curing method may be either heat or light. The resin layers of the semiconductor dies 4 and 5 may be in a cured state not reaching a completely cured state as long as there is no problem as the semiconductor device 1. The curable resin composition constituting the resin layers of the semiconductor dies 4 and 5 contains a thermosetting resin. The curable resin composition may further contain a curing agent, a curing accelerator, and an inorganic filler.

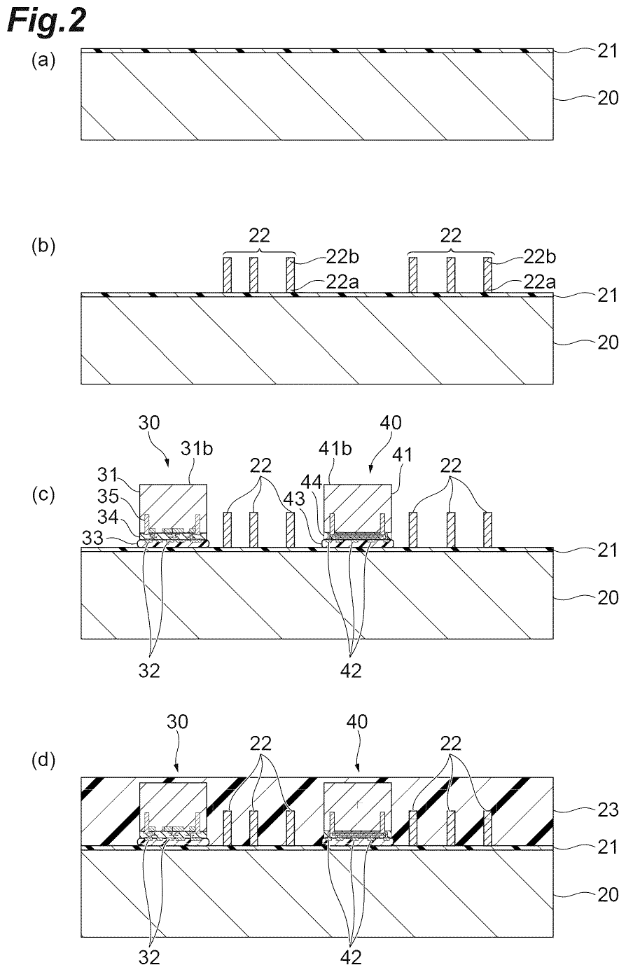

Next, an example of a method for manufacturing the semiconductor device 1 will be described with reference to FIGS. 2 to 6. FIG. 2 and FIGS. 4 to 6 are cross-sectional views sequentially illustrating the method for manufacturing the semiconductor device 1. FIG. 3 is an enlarged cross-sectional view of a semiconductor member.

In this method for manufacturing a semiconductor device, as illustrated in FIG. 2 (a), first, a temporary fixing layer 21 is formed on a carrier substrate 20 (first support). The carrier substrate 20 is, for example, a glass substrate. The temporary fixing layer 21 is, for example, a curable adhesive layer, and is configured to be peeled off together with the carrier substrate 20 by light, heat, or the like in a step described later.

Subsequently, as illustrated in FIG. 2 (b), a plurality of posts 22 are formed on the temporary fixing layer 21. Each post 22 is a conductive post member, and is formed of, for example, copper. Each post 22 has a first end 22a and a second end 22b on the opposite side, and is formed such that the first end 22a of each post 22 is located on the carrier substrate 20 side. The post 22 corresponds to the connection electrode 10 illustrated in FIG. 1. Since the semiconductor dies 30 and 40 are installed on the carrier substrate 20 (temporary fixing layer 21) in a step described later, the posts 22 are not installed in the region. Such a post 22 can be produced, for example, by a semi-additive method. The height of the post 22 may be, for example, 50 μm to 200 μm, or 75 μm to 180 μm. Furthermore, the diameter of the post 22 may be, for example, 10 μm to 50 μm.

Subsequently, as illustrated in FIG. 3(a) and 3(b), the semiconductor dies 30 and 40 (semiconductor members) are prepared. As illustrated in FIG. 3 (a), the semiconductor die 30 includes a semiconductor substrate 31, a plurality of terminal electrodes 32, a resin layer 33, a fine wiring layer 34, and internal electrodes 35. The semiconductor die 30 corresponds to the semiconductor die 5 illustrated in FIG. 1. The semiconductor substrate 31 is formed of, for example, silicon or the like, and has a first surface 31a and a second surface 31b on the opposite side. The plurality of terminal electrodes 32 are provided on the first surface 31a side of the semiconductor substrate 31. The plurality of terminal electrodes 32 are, for example, copper pillars provided on the first surface 31a side of the semiconductor substrate 31, and are connected to wiring (not illustrated) in the semiconductor substrate 31. The diameter of each terminal electrode 32 is, for example, 10 μm to 50 μm, a terminal pitch (a separation distance) between the terminal electrodes 32 is, for example, 5 μm to 20 μm, and the height of the terminal electrode 32 is, for example, 20 μm to 50 μm. However, the size of the terminal electrode 32 is not limited thereto.

The resin layer 33 is a resin member formed of a thermosetting adhesive (curable resin composition) provided on the first surface 31a side so as to cover the plurality of terminal electrodes 32. The resin layer 33 may be formed so as to cover the entire first surface 31a of the semiconductor substrate 31, or may be formed so that the tip of the terminal electrode 32 is exposed from the surface of the resin layer 33. The semiconductor die 30 is attached (pasted) onto the temporary fixing layer 21 of the carrier substrate 20 by the resin layer 33. The resin layer 33 can be formed, for example, by bonding (pasting) a resin film containing a resin composition such as a non-conductive adhesive film (NCF) or a die attach film (DAF). The resin film before being bonded may be 75% and 150% or between 100% and 120% with respect to the height of the plurality of terminal electrodes 32, and is preferably a film having the same thickness as the height of the terminal electrodes 32. The resin layer 33 is a semi-cured or uncured curable resin composition when the semiconductor die 30 is attached to the carrier substrate 20. Such a resin layer 33 may have a transmittance of 30% or more with respect to visible light, preferably has a transmittance of 50% or more with respect to visible light, and more preferably has a transmittance of 80% or more with respect to visible light. In this case, when the semiconductor die 30 is attached to the carrier substrate 20 in a step described later, the positions of the plurality of terminal electrodes 32 are determined through the resin layer 33, and the semiconductor die 30 can be attached to a predetermined position of the carrier substrate 20 with high accuracy based on a result of the determination. Note that the resin layer 33 may be formed by applying a liquid adhesive containing a thermosetting adhesive (a curable resin composition) similar to the resin film to the first surface 31a of the semiconductor substrate 31.

The thickness of the resin layer 33 may be, for example, 50 μm or less, 20 μm or less, 10 μm or less, 9 μm or less, 8 μm or less, or 7 μm or less, and may be 1 μm or more, 2 μm or more, 3 μm or more, 4 μm or more, 5 μm or more, or 10 μm or more. The thickness of the resin layer 33 may be between 100% to 150% or between 100% to 120% with respect to the height of the plurality of terminal electrodes 32, and is preferably the same thickness as the height of the terminal electrodes 32. Note that the thickness of the resin layer 33 referred to here means the thickness in an uncured or semi-cured state, and the height of the plurality of terminal electrodes 32 means an average of the heights of the plurality of terminal electrodes 32.

The fine wiring layer 34 is a wiring layer located between the semiconductor substrate 31 and the resin layer 33. The fine wiring layer 34 includes a wiring portion 34a and an insulating portion 34b covering the wiring portion 34a. The wiring portion 34a electrically connects the wiring in the semiconductor substrate 31 or the internal electrode 35 with the terminal electrode 32. The semiconductor die 30 may not have the fine wiring layer 34.

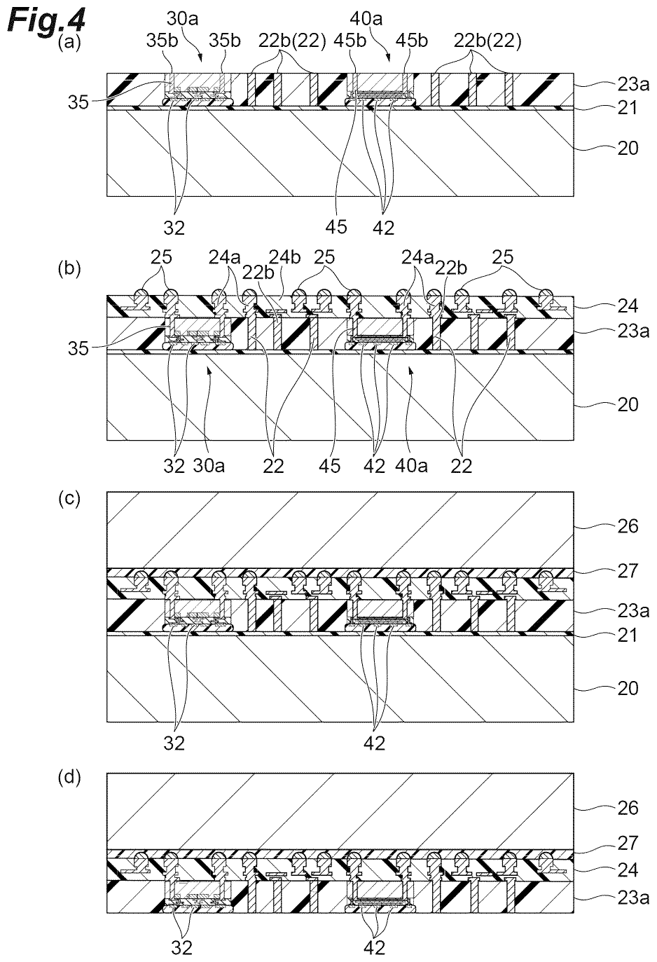

The internal electrode 35 is an electrode that connects wiring layers provided on both surfaces of the semiconductor die 30, and is formed to extend in the thickness direction of the semiconductor substrate 31. The internal electrode 35 corresponds to the through electrode 4c illustrated in FIG. 1. The internal electrode 35 has a first end 35a and a second end 35b on the opposite side. The first end 35a is connected to the corresponding terminal electrode 32 via the fine wiring layer 34. On the other hand, the second end 35b of the internal electrode 35 is not exposed to the outside in a stage where the semiconductor die 30 is attached to the carrier substrate 20 (stage of FIG. 2 (c)), and is located within the semiconductor substrate 31. By grinding the second surface 31b of the semiconductor substrate 31 in a step described later (stage of FIG. 4 (a)), the second end 35b of the internal electrode 35 is exposed to the outside, and the internal electrode 35 functions as a through electrode. The semiconductor die 30 may not have the internal electrode 35 serving as a through electrode.

The semiconductor die 40 has the same configuration as that of the semiconductor die 30, and as illustrated in FIG. 3 (b), includes a semiconductor substrate 41, a plurality of terminal electrodes 42, a resin layer 43, a fine wiring layer 44, and internal electrodes 45. The semiconductor die 40 corresponds to the semiconductor die 4 illustrated in FIG. 1. The semiconductor substrate 41 is formed of, for example, silicon or the like, and has a first surface 41a and a second surface 41b on the opposite side. The plurality of terminal electrodes 42 are provided on the first surface 41a side of the semiconductor substrate 41. The plurality of terminal electrodes 42 are connected to wiring (not illustrated) in the semiconductor substrate 41. The size, height, and the like of the terminal electrode 42 are similar to those of the terminal electrode 32. The resin layer 43 is an adhesive member provided on the first surface 41a side so as to cover the plurality of terminal electrodes 42. The semiconductor die 40 is attached (pasted) onto the temporary fixing layer 21 of the carrier substrate 20 by the resin layer 43. The resin layer 43 can be formed, for example, by bonding (pasting) a resin film containing a resin composition such as an NCF or a DAF. The resin film before being bonded may be 75% and 150% or between 100% and 120% with respect to the height of the plurality of terminal electrodes 42, and is preferably a film having the same thickness as the height of the terminal electrodes 42. The resin layer 43 is a semi-cured or uncured curable resin composition when the semiconductor die 40 is attached to the carrier substrate 20. As the resin composition constituting the resin layer 43, the same one as that of the resin layer 33 can be used.

The fine wiring layer 44 is a wiring layer located between the semiconductor substrate 41 and the resin layer 43. The fine wiring layer 44 includes a wiring portion 44a and an insulating portion 44b covering the wiring portion 44a. The wiring portion 44a electrically connects the wiring in the semiconductor substrate 41 or the internal electrode 45 with the terminal electrode 42. The internal electrode 45 is an electrode connecting wiring layers provided on both surfaces of the semiconductor die 40, and has a first end 45a and a second end 45b on the opposite side. The first end 45a is connected to the corresponding terminal electrode 42 via the fine wiring layer 44. The second end 45b is not exposed to the outside in a stage where the semiconductor die 40 is attached to the carrier substrate 20. By grinding the second surface 41b of the semiconductor substrate 41, the second end 45b of the internal electrode 45 is exposed to the outside, and the internal electrode 45 functions as a through electrode. The semiconductor die 40 may not have the fine wiring layer 44 and the internal electrodes 45.

Note that each of the semiconductor dies 30 and 40 described above can be manufactured by dividing a wafer or a panel-shaped semiconductor substrate including a large number of semiconductor dies 30 and 40 having the above-described layer configuration.

Here, an example of the adhesive constituting the resin layers 33 and 43 will be described. As such an adhesive, an adhesive containing (a) an epoxy resin, (b) a curing agent, (c) a high-molecular-weight component having a weight average molecular weight of 10000 or more, (d) inorganic fillers having an average particle size of 100 nm or less, and (e) a glycidyl-based silane coupling agent can be used. In this adhesive, the content of the (d) inorganic filler may be 20 to 40 mass %. Note that the adhesive constituting the resin layers 33 and 43 is not limited to the adhesive described below.

Examples of the epoxy resin as the component (a) include epoxy resins having two or more epoxy groups in the molecule, and bisphenol A-type epoxy resin, bisphenol F-type epoxy resin, naphthalene-type epoxy resin, phenol novolac-type epoxy resin, cresol novolac-type epoxy resin, phenol aralkyl-type epoxy resin, biphenyl-type epoxy resin, triphenylmethane-type epoxy resin, dicyclopentadiene-type epoxy resin, various polyfunctional epoxy resins can be used. The component (a) can be used alone or in combination of two or more kinds thereof. The content of the component (a) is, for example, 10 to 50 mass % based on the total amount of the thermosetting adhesive.

Examples of the curing agent as the component (b) include a phenol resin-based curing agent, an acid anhydride-based curing agent, an amine-based curing agent, an imidazole-based curing agent, and a phosphine-based curing agent. When the component (b) contains a phenolic hydroxyl group, an acid anhydride, an amine, or an imidazole, it is easy to exhibit flux activity for preventing formation of an oxide film at the connection portion, and connection reliability and insulation reliability can be easily improved. Each curing agent will be described below.

### (i) Phenol Resin-Based Curing Agent

Examples of the phenol resin-based curing agent include curing agents having two or more phenolic hydroxyl groups in the molecule, and phenol novolac, cresol novolac, phenol aralkyl resin, cresol naphthol formaldehyde polycondensate, triphenylmethane-type polyfunctional phenol, various polyfunctional phenol resins can be used. The phenol resin-based curing agent can be used alone or in combination of two or more kinds thereof.

The equivalent ratio of the phenol resin-based curing agent to the component (a) (phenolic hydroxyl group/epoxy group, molar ratio) is preferably 0.3 to 1.5, more preferably 0.4 to 1.0, and further preferably 0.5 to 1.0, from the viewpoint of excellent curability, adhesiveness, and storage stability. When the equivalent ratio is 0.3 or more, there is a tendency that curability is improved and adhesive force is improved. When the equivalent ratio is 1.5 or less, there is a tendency that an unreacted phenolic hydroxyl group does not excessively remain, the water absorption is decreased to be low, and insulation reliability is further improved.

### (ii) Acid Anhydride-Based Curing Agent

As the acid anhydride-based curing agent, for example, methylcyclohexanetetracarboxylic dianhydride, trimellitic anhydride, pyromellitic anhydride, benzophenonetetracarboxylic dianhydride, and ethylene glycol bisanhydrotrimellitate can be used. The acid anhydride-based curing agent can be used alone or in combination of two or more kinds thereof.

The equivalent ratio of the acid anhydride-based curing agent to the component (a) (acid anhydride group/epoxy group, molar ratio) is preferably 0.3 to 1.5, more preferably 0.4 to 1.0, and further preferably 0.5 to 1.0, from the viewpoint of excellent curability, adhesiveness, and storage stability. When the equivalent ratio is 0.3 or more, there is a tendency that curability is improved and adhesive force is improved. When the equivalent ratio is 1.5 or less, there is a tendency that an unreacted acid anhydride does not excessively remain, the water absorption is decreased to be low, and insulation reliability is further improved.

### (iii) Amine-Based Curing Agent

As the amine-based curing agent, for example, dicyandiamide can be used.

The equivalent ratio of the amine-based curing agent to the component (a) (amine/epoxy group, molar ratio) is preferably 0.3 to 1.5, more preferably 0.4 to 1.0, and further preferably 0.5 to 1.0, from the viewpoint of excellent curability, adhesiveness, and storage stability. When the equivalent ratio is 0.3 or more, there is a tendency that curability is improved and adhesive force is improved. When the equivalent ratio is 1.5 or less, there is a tendency that an unreacted amine does not excessively remain, and insulation reliability is further improved.

### (iv) Imidazole-Based Curing Agent

Examples of the imidazole-based curing agent include 2-phenylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, an isocyanuric acid adduct of 2,4-diamino-6-[2′-methylimidazolyl-(1′)]-ethyl-s-triazine, an isocyanuric acid adduct of 2-phenylimidazole, 2-phenyl-4,5-dihydroxymethylimidazole, 2-phenyl-4-methyl-5-hydroxymethylimidazole, and an adduct of epoxy resin and imidazole. Among the examples, from the viewpoint of further excellent curability, storage stability, and connection reliability, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-ethyl-4′-methylimidazolyl-(1′)]-ethyl-s-triazine, an isocyanuric acid adduct of 2,4-diamino-6-[2′-methylimidazolyl-(1′)]-ethyl-s-triazine, an isocyanuric acid adduct of 2-phenylimidazole, 2-phenyl-4,5-dihydroxymethylimidazole, and 2-phenyl-4-methyl-5-hydroxymethylimidazole are preferable. The imidazole-based curing agent can be used alone or in combination of two or more kinds thereof. Further, the examples may be microencapsulated and used as a latent curing agent.

The content of the imidazole-based curing agent is preferably 0.1 to 20 parts by mass and more preferably 0.1 to 10 parts by mass with respect to 100 parts by mass of the component (a). When the content of the imidazole-based curing agent is 0.1 parts by mass or more, there is a tendency that curability is improved, when the content thereof is 20 parts by mass or less, there is a tendency that an adhesive composition is not cured before formation of metal bonding, and a connection failure hardly occurs.

### (v) Phosphine-Based Curing Agent

Examples of the phosphine-based curing agent include triphenylphosphine, tetraphenylphosphonium tetraphenylborate, tetraphenylphosphonium tetra(4-methylphenyl)borate, and tetraphenylphosphonium (4-fluorophenyl)borate.

The content of the phosphine-based curing agent is preferably 0.1 to 10 parts by mass and more preferably 0.1 to 5 parts by mass with respect to 100 parts by mass of the component (a). When the content of the phosphine-based curing agent is 0.1 parts by mass or more, there is a tendency that curability is improved. When the content thereof is 10 parts by mass or less, there is a tendency that an adhesive for a semiconductor is not cured before formation of metal bonding and a connection failure hardly occurs.

Each of the phenol resin-based curing agent, the acid anhydride-based curing agent, and the amine-based curing agent can be used alone or in combination of two or more kinds thereof. The imidazole-based curing agent and the phosphine-based curing agent may be used alone, or may be used together with a phenol resin-based curing agent, an acid anhydride-based curing agent, or an amine-based curing agent.

As the component (b), from the viewpoint of excellent curability, a combination of phenol and imidazole, a combination of acid anhydride and imidazole, a combination of amine and imidazole, and a single use of imidazole are preferable. A single use of imidazole, which is excellent in rapid curability, is more preferable because the connection is made in a short time to improve productivity. In this case, when the component is cured in a short time, volatile components such as low-molecular-weight components can be decreased, so that generation of voids can also be easily prevented.

Examples of the high-molecular-weight component (c) having a weight average molecular weight of 10000 or more (excluding a compound corresponding to the component (a)) include phenoxy resin, polyimide resin, polyamide resin, polycarbodiimide resin, cyanate ester resin, (meth)acrylic resin, polyester resin, polyethylene resin, polyethersulfone resin, polyetherimide resin, polyvinyl acetal resin, urethane resin, acrylic rubber, and among these, from the viewpoint of excellent heat resistance and film formability, phenoxy resin, polyimide resin, (meth)acrylic resin, acrylic rubber, cyanate ester resin, polycarbodiimide resin, and the like are preferable, phenoxy resin, polyimide resin, (meth)acrylic resin, and acrylic rubber are more preferable. The component (c) can be used alone or as a mixture or copolymer of two or more kinds thereof.

The mass ratio of the component (c) and the component (a) is not particularly limited, but in order to retain a film shape, the content of the component (a) is preferably 0.01 to 5 parts by mass, more preferably 0.05 to 4 parts by mass, and further preferably 0.1 to 3 parts by mass, with respect to 1 part by mass of the component (c). When the content is 0.01 parts by mass or more, there is a tendency that curability is improved and adhesive force is improved. When the content is 5 parts by mass or less, there is a tendency that film formability and membrane formability are improved.

The weight average molecular weight of the component (c) is 10000 or more in terms of polystyrene, but is preferably 30000 or more, more preferably 40000 or more, and 50000 or more in order to exhibit favorable film formability by itself. When the weight average molecular weight is 10000 or more, there is a tendency that film formability is improved. Note that, in the present specification, the weight average molecular weight means a weight average molecular weight measured in terms of polystyrene using high-performance liquid chromatography (C-R4A manufactured by SHIMADZU CORPORATION).

The component (d) is not particularly limited as long as it is inorganic fillers having an average particle size of 100 nm or less, and examples thereof include insulating inorganic fillers. Examples of the insulating inorganic fillers include glass, silica, alumina, titanium oxide, carbon black, mica, and boron nitride, and among these, silica, alumina, titanium oxide, boron nitride are preferable, and silica, alumina, and boron nitride are more preferable. The insulating inorganic fillers may be a whisker, and examples of the whisker include aluminum borate, aluminum titanate, zinc oxide, calcium silicate, magnesium sulfate, and boron nitride. The insulating inorganic fillers can be used alone or in combination of two or more kinds thereof. The shape, particle size, and content of the component (d) are not particularly limited. The component (d) can be used alone or in combination of two or more kinds thereof.

The average particle size of the component (d) is 100 nm or less from the viewpoint of improving visibility. The average particle size of the component (d) is preferably 60 nm or less from the viewpoint of improving visibility. From the viewpoint of improving the adhesive force, the component (d) is preferably inorganic fillers each surface-treated with a (meth)acrylic silane and having an average particle size of 60 nm or less.

The content of the component (d) is 20 to 40 mass % based on the total amount of the adhesive. When the content of the component (d) is 20 mass % or more, there is a tendency that the adhesive force is high and reflow resistance is improved. When the content of the component (d) is 40 mass % or less, thickening can be prevented to improve connection reliability.

The component (e) is not particularly limited as long as it is a glycidyl-based silane coupling agent. In the case of a glycidyl-based silane coupling agent, the adhesive force is improved by using the glycidyl-based silane coupling agent in combination with an epoxy resin. The content of the component (e) is preferably 1 to 5 parts by mass and more preferably 1.5 to 4 mass % with respect to 100 parts by mass of the component (d). When the content is 1 part by mass or more, there is a tendency that the adhesive force is improved, and when the content is 5 parts by mass or less, defects such as generation of voids can be prevented.

Note that the adhesive according to the present embodiment may further contain additives such as a flux agent, resin fillers, an antioxidant, a silane coupling agent (excluding a compound corresponding to the component (e)), a titanium coupling agent, and a leveling agent. These additives can be used alone or in combination of two or more kinds thereof. The content of these additives may be appropriately adjusted so that the effect of each additive is exhibited.

Furthermore, as a different type of adhesive constituting the resin layers 33 and 43, an adhesive containing a high molecular weight resin component and a thermosetting component may be used. The high molecular weight resin component may contain, for example, at least one resin selected from the group consisting of acrylic rubber, polyimide, and phenoxy resin. The high molecular weight resin component may have a reactive group such as an epoxy group. A weight average molecular weight (value in terms of standard polystyrene by a GPC method) of the high molecular weight resin component may be 100000 to 3000000. The content of the high molecular weight resin component may be 30 to 80 parts by mass with respect to 10 parts by mass of the total mass of the resin layer 33.

The thermosetting component contained in this different type of adhesive is a compound having a reactive group that forms a crosslinked structure by self-polymerization and/or reaction with a curing agent. The thermosetting component may contain, for example, at least one selected from the group consisting of an epoxy resin, a bismaleimide resin, a triazine resin, and a phenol resin. The content of the thermosetting component may be 1 to 30 parts by mass with respect to 100 parts by mass of the amount of the resin layer 33. This different type of adhesive may contain other components as necessary. Examples of other components include a curing agent that reacts with the thermosetting component, a curing accelerator that accelerates the reaction between the thermosetting component and the curing agent, a coupling agent (for example, a silane coupling agent), and inorganic fillers (for example, silica).

A specific example of the inorganic fillers contained in this different type of adhesive is glass as described above. Furthermore, the average particle diameter of the inorganic fillers may be, for example, 20 μm or less, or 10 μm or less, and the maximum particle diameter of the inorganic fillers may be, for example, 30 μm or less. It is preferable that an average particle diameter of the inorganic fillers be 5 μm or less, and a maximum particle diameter of the inorganic fillers be 20 μm or less. When the average particle diameter is 10 μm or less and the maximum particle diameter is 30 μm or less, a space between the terminals can be filled without a gap when the resin layer is formed on a terminal surface, and warpage of the resin layer after curing can be prevented. A lower limit of the average particle diameter and a lower limit of the maximum particle diameter of the inorganic fillers are not particularly limited, and both may be 0.001 μm or more.

Examples of a method for measuring the average particle diameter and the maximum particle diameter of the inorganic fillers include a method for measuring a particle diameter of about 20 inorganic fillers using a scanning electron microscope (SEM). Examples of the measurement method using the SEM include a method in which a sample in which a resin composition containing inorganic fillers is heat-cured (preferably at 150 to 180° C. for 1 to 10 hours) is prepared, a central portion of the sample is cut, and a cross-section thereof is observed with an SEM. In this case, an existence probability of the fillers each having a particle diameter of 3 μm or less in the cross section is preferably 80% or more of all fillers.

Furthermore, the content of the inorganic fillers may be 10 mass % to 95 mass % based on the total solid content contained in the adhesive before curing. The content of the inorganic fillers contained in the adhesive is preferably 20 mass % or more, more preferably 30 mass % or more, particularly preferably 40 mass % or more, and preferably 40 mass % to 95 mass %, based on the total solid content contained in the adhesive (resin layers 33 and 43) before curing. The elastic modulus (Young's modulus, after curing) of such a resin layer 33 may be, for example, 10 MPa or more or 1.0 GPa or more at room temperature (25° C.). Also, the linear expansion coefficient of the resin layer 33 at a temperature equal to or lower than a glass transition temperature may be, for example, 10 ppm/K to 200 ppm/K.

Returning to FIG. 2, the description will be continued. When the preparation of the semiconductor dies 30 and 40 is completed, as illustrated in FIG. 2 (c), the semiconductor dies 30 and 40 are attached to the carrier substrate 20 such that the lower surfaces provided with the terminal electrodes 32 and 42 (see FIG. 3(a) and 3(b)) face the carrier substrate 20. At this time, the entire upper surfaces (second surfaces 31b and 41b) of the semiconductor dies 30 and 40 are vacuum-sucked by a collet to perform bonding. The collet is formed of, for example, an elastic member such as rubber. The semiconductor dies 30 and 40 are moved to a predetermined position on the carrier substrate 20 by a collet sucked under vacuum, and are attached to the predetermined position of the carrier substrate 20 by the resin layers 33 and 43. At the time of this attachment, since the terminal electrodes 32 and 42 of the semiconductor dies 30 and 40 are covered with the resin layers 33 and 43, the terminal electrodes 32 and 42 are protected. As a result, a state illustrated in FIG. 2 (c) is obtained. In this step, the semiconductor dies 30 and 40 are arranged such that the terminal electrodes 32 and 42 are in a face-down state facing downward.

When the semiconductor dies 30 and 40 are attached, positions of the terminal electrodes 32 and 42 in the planar direction are determined through the resin layers 33 and 43 of the semiconductor dies 30 and 40, and the semiconductor dies 30 and 40 may be attached to predetermined positions of the carrier substrate 20 based on a result of the determination. When the resin layers 33 and 43 have a predetermined transmittance or more (for example, when the transmittance with respect to visible light is 30% or more), such position determination before attachment can be performed, and the positional relationship between the terminal electrodes 32 and 42 and the posts 22 can be made highly accurate. When the carrier substrate 20 is a transmissive member such as a glass substrate, the posts 22 and the terminal electrodes 32 and 42 can be positioned from below the carrier substrate 20. The positions of the terminal electrodes 32 and 42 may be directly determined through the resin layers 33 and 43, or the positions of the terminal electrodes 32 and 42 may be indirectly determined by determining the positions of the positioning markings provided on the surfaces on the first surfaces 31a and 41a side through the resin layers 33 and 43. The position determination of the terminal electrodes 32 and 42 may be performed by other methods, and is not particularly limited.

Subsequently, when the attachment of the semiconductor dies 30 and 40 is completed, the resin layers 33 and 43 containing a curable resin composition are cured before the semiconductor dies 30 and 40 are encapsulated. The resin layers 33 and 43 are cured using either one or both of heat and light. As a result, the semiconductor dies 30 and 40 are fixed to the carrier substrate 20. Note that the fixing described here is sufficient as long as the semiconductor dies 30 and 40 are fixed to the extent that positional deviation does not occur in the encapsulating described later.

Subsequently, as illustrated in FIG. 2 (d), an encapsulant layer 23 (first encapsulant layer) encapsulating the plurality of posts 22 and the semiconductor dies 30 and 40 with an encapsulant is formed on the carrier substrate 20. The encapsulant layer 23 is formed to contain a thermosetting resin such as an epoxy resin, for example, and is cured by heat or the like after encapsulating is performed. The resin layers 33 and 43 of the semiconductor dies 30 and 40 may be further cured by the thermal curing. The encapsulant constituting the encapsulant layer 23 contains a thermosetting resin composition, and contains, for example, an epoxy resin and a curing agent. The encapsulant constituting the encapsulant layer 23 may further contain inorganic fillers, for example, contains silica fillers. An average particle diameter of the inorganic fillers contained in the encapsulant may be, for example, 50 μm or less, 25 μm or less, 10 μm or less, or 0.01 μm or less. The encapsulant constituting the encapsulant layer 23 preferably contains inorganic filler having a large particle diameter, and preferably contains inorganic fillers having an average particle diameter larger than the average particle diameter of the inorganic fillers contained in the resin layer 33 or 43 of the semiconductor die 30 or 40, in order to prevent warpage in manufacturing or after manufacturing the semiconductor device 1.

Subsequently, when the encapsulant layer 23 is formed, the encapsulant layer is ground by CMP or the like, and as illustrated in FIG. 4 (a), the encapsulant layer is thinned to a ground encapsulant layer 23a. The elastic modulus (Young's modulus) of the encapsulant layers 23 and 23a may be, for example, 3.0 GPa or more. The linear expansion coefficient of the encapsulant layers 23 and 23a may be 5 ppm/K to 150 ppm/K, and a difference from the linear expansion coefficient of the resin layers 33 and 43 is 100 ppm/K or less. By this grinding, semiconductor dies 30a and 40a, in which the second ends 35b and 45b being the tips of the internal electrodes 35 and 45 become exposed to the outside of the encapsulant layer 23a, are formed. Furthermore, by this grinding, the second ends 22b of the posts 22 are also exposed to the outside of the encapsulant layer 23a. The second ends 22b of the posts 22 may be slightly ground.

Subsequently, when the encapsulant layer 23a is formed, as illustrated in FIG. 4 (b), a wiring layer 24 (first wiring layer) is formed on the encapsulant layer 23a. The wiring layer 24 may be, for example, a redistribution layer (RDL). The wiring layer 24 is provided with wiring portions 24a and an insulating portion 24b covering the wiring portions 24a. The wiring portions 24a connect semiconductor dies 50 and 55 described later with an external device, and are connected to, for example, the second end 22b of each post 22 and the second ends 35b and 45b of the internal electrodes 35 and 45 of the semiconductor dies 30a and 40a. The wiring portions 24a may include, for example, copper pillars. A known method can be used as a method for manufacturing the wiring layer 24 including the wiring portions 24a. Note that, in this manufacturing method, as described above, since the positioning of the posts 22 and the semiconductor dies 30 and 40 is performed with high accuracy, the wiring portions 24a can be formed using mask exposure. In this case, the manufacturing efficiency of the wiring layer 24 can be significantly improved. Furthermore, connection bumps 25 may be formed on terminals on the opposite side (upper side in the drawing) of the wiring portions 24a. The connection bumps 25 may be, for example, solder bumps.

Subsequently, when the wiring layer 24 is formed, as illustrated in FIG. 4 (c), a carrier substrate 26 (second support) is provided on the wiring layer 24. As a result, the structure including the encapsulant layer 23a, the wiring layer 24, and the like is sandwiched between the carrier substrate 20 and the carrier substrate 26. When the carrier substrate 26 is provided, a temporary fixing layer 27 may be provided on the wiring layer 24 side. The same temporary fixing layer as the temporary fixing layer 21 can be used as the temporary fixing layer 27. When the connection bumps 25 are formed, the temporary fixing layer 27 preferably has such a thickness that the connection bumps 25 are protected.

Subsequently, when the carrier substrate 26 is provided, as illustrated in FIG. 4 (d), the carrier substrate 20 is separated from the encapsulant layer 23a. In this separation, laser light irradiation or heat treatment is performed on the temporary fixing layer 21 to lower the adhesiveness of the temporary fixing layer 21 and separate the carrier substrate 20 from the encapsulant layer 23a by peeling.

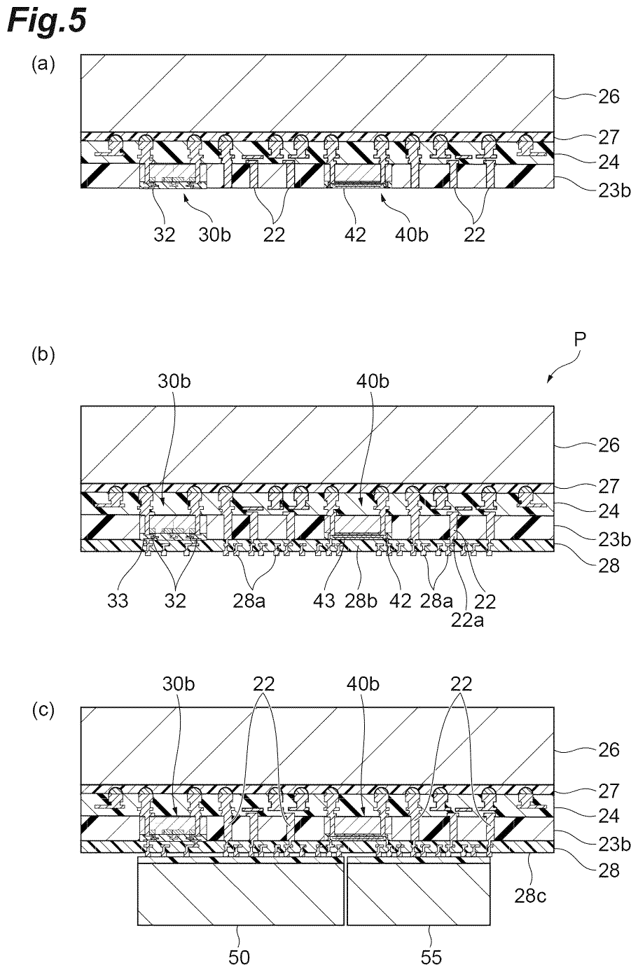

Subsequently, when the carrier substrate 20 is separated, the encapsulant layer 23a is ground by CMP or the like, and as illustrated in FIG. 5 (a), the encapsulant layer 23a is further thinned to a ground encapsulant layer 23b. In this grinding, grinding is performed until the terminal electrodes 32 and 42 provided in the resin layers 33 and 43 of the semiconductor dies 30b and 40b are exposed to the outside. The thickness of the ground resin layers 33 and 43 may be 20 μm or more. When the encapsulant layer 23a including the resin layers 33 and 43 is ground, tip portions of the terminal electrodes 32 and 42 and tip portions of the posts 22 may also be ground in the same manner. Such grinding may be grinding with a grinder or the like, or may be etching processing. It is preferable to perform a cleaning treatment after grinding.

Subsequently, when the grinding of the encapsulant layer is completed and the terminal electrodes 32 and 42 are exposed to the outside, as illustrated in FIG. 5 (b), the wiring layer 28 (second wiring layer) electrically connected to the terminal electrodes 32 and 42 and the posts 22 is formed on the encapsulant layer 23b on which the resin layers 33 and 43 have been ground. The wiring layer 28 may be, for example, a redistribution layer (RDL). The wiring layer 28 is provided with wiring portions 28a and an insulating portion 28b covering the wiring portions 28a. The wiring portions 28a connect the plurality of posts 22 and the semiconductor dies 30b and 40b to the semiconductor dies 50 and 55 described later, and are connected to, for example, the first end 22a of each post 22, the terminal electrodes 32 and 42 of the semiconductor dies 30b and 40b, and first ends 35a and 45a of the internal electrodes 35 and 45. The wiring portions 28a may include, for example, copper pillars. A known method can be used as a method for manufacturing the wiring layer 28 including the wiring portions 28a, similarly to the wiring layer 24. Note that, in this manufacturing method, as described above, since the positioning of the posts 22 and the terminal electrodes 32 and 42 of the semiconductor dies 30b and 40b is performed with high accuracy, the wiring layer 28 can be formed using mask exposure. In this case, the manufacturing efficiency of the wiring layer 28 can be significantly improved. The wiring pitch and the wiring width of the wiring portions 28a are preferably smaller than the wiring pitch and the wiring width of the wiring portions 24a. As a result, the semiconductor dies 50 and 55 having a fine structure can be connected. As described above, an interposer P (wiring board) is manufactured. Note that connection points (first connection point) between the posts 22 and the wiring layer 24 and connection points (second connection point) between the posts 22 and the terminal electrodes 32 and 42, and the wiring layer 28, are connected in a solderless manner.

Subsequently, when the wiring layer 28 is formed, as illustrated in FIG. 5 (c), the semiconductor dies 50 and 55 (first semiconductor chip, second semiconductor chip) are attached to a surface 28c (lower surface in the drawing) of the wiring layer 28 on a side opposite to the encapsulant layer 23b. At this time, the terminal electrodes of the semiconductor dies 50 and 55 are connected to the tips of the wiring portions 28a of the wiring layer 28. This connection may be a connection via solder. The semiconductor dies 50 and 55 are, for example, semiconductor chips such as an LSI chip (logic chip), a CMOS sensor, and a memory chip, and may be so-called active dies. The semiconductor dies 50 and 55 correspond to the semiconductor dies 3 and 2 illustrated in FIG. 1. Here, one or more semiconductor chips may be attached, but it is preferable to attach two or more semiconductor chips. In this step, the semiconductor die 50 and the semiconductor die 55 are electrically connected to each other by the embedded semiconductor die 40b. The embedded semiconductor die 30b is connected to the semiconductor die 50. Similarly, each post 22 is connected to the semiconductor dies 50 and 55 via the wiring layer 28.

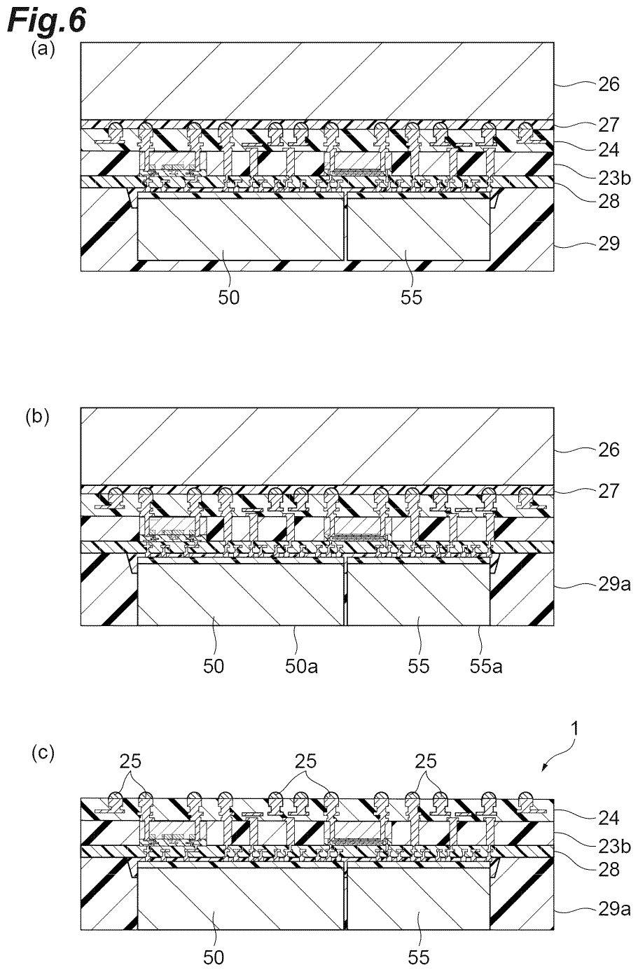

Subsequently, when the semiconductor dies 50 and 55 are mounted, as illustrated in FIG. 6 (a), the semiconductor dies 50 and 55 are encapsulated with an encapsulant on the wiring layer 28, and an encapsulant layer 29 (second encapsulant layer) is formed on the wiring layer 28. Similarly to the encapsulant layer 23, the encapsulant layer 29 contains a thermosetting resin such as an epoxy resin, for example, and is cured after encapsulating is performed.

Subsequently, when the semiconductor dies 50 and 55 are encapsulated with the encapsulant to form the encapsulant layer 29, as illustrated in FIG. 6 (b), grinding may be performed until surfaces 50a and 55a of the semiconductor dies 50 and 55 are exposed from the surface of the encapsulant layer. As a result, the encapsulant layer 29 is thinned to an encapsulant layer 29a illustrated in FIG. 6 (b).

Subsequently, when the encapsulant layer is thinned to the encapsulant layer 29a, as illustrated in FIG. 6 (c), laser light irradiation or heat treatment is performed on the temporary fixing layer 27 to lower the adhesiveness of the temporary fixing layer 27 and separate the carrier substrate 26 from the wiring layer 24 by peeling. As a result, the connection bumps 25 are exposed to the outside. In the above description, an example has been described in which the connection bumps 25 are produced by the step illustrated in FIG. 4 (b), but the present invention is not limited thereto, and the connection bumps 25 may be provided in the wiring layer 24 after the temporary fixing layer 27 is separated.

As described above, the semiconductor device 1 illustrated in FIG. 6(c) and FIG. 1 is manufactured. Such a semiconductor device 1 is mounted on the substrate M. At this time, an underfill material is applied between the semiconductor device 1 and the substrate M. Thereafter, the underfill material is cured by thermal curing or the like, thereby manufacturing the semiconductor device (structure S) illustrated in FIG. 1.

As described above, in the method for manufacturing a semiconductor device according to the first embodiment, the semiconductor dies 30 and 40 are attached to the carrier substrate 20 such that the first surfaces 31a and 41a provided with the terminal electrodes 32 and 42 face the carrier substrate 20. That is, the semiconductor dies 30 and 40 are attached in a face-down manner. Therefore, when the semiconductor dies 30 and 40 are sucked by a collet or the like and bonded, it is not necessary to suck the terminal electrode side, and the semiconductor dies 30 and 40 can be reliably attached. Note that, when the semiconductor dies 30 and 40 are picked up before bonding, the terminal electrodes 32 and 42 side may be once sucked by a collet (and then turned over to perform bonding), and in this case, since the terminal electrodes 32 and 42 are covered with the resin layers 33 and 43, the outer periphery does not need to be sucked by the collet, and the semiconductor dies 30 and 40 can be reliably picked up.

Furthermore, in this method for manufacturing a semiconductor device, the semiconductor dies 50 and 55 connected to the semiconductor dies 30 and 40 can be attached at the end of the process (for example, after forming the wiring layer 24 and the wiring layer 28). Thereby, when a defect occurs at an intermediate stage, it is possible not to attach the semiconductor dies 50 and 55 which are expensive active dies. As a result, the overall manufacturing cost can be reduced.

### Second Embodiment

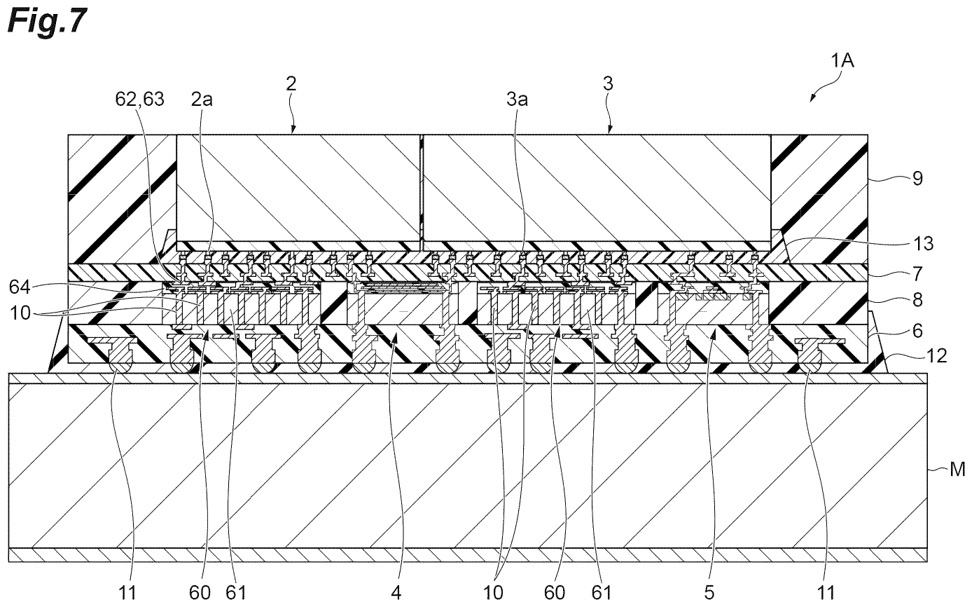

Next, a semiconductor device according to a second embodiment and a method for producing the same will be described with reference to FIGS. 7 to 11. Description of points overlapping with the semiconductor device and the method for manufacturing the same according to the first embodiment may be omitted.

FIG. 7 is a view illustrating an example of a semiconductor device manufactured by a manufacturing method according to a second embodiment. As illustrated in FIG. 7, a semiconductor device 1A includes semiconductor dies 2 and 3, semiconductor dies 4 and 5, wiring layers 6 and 7, encapsulant layers 8 and 9, connection bumps 11, and underfills 12 and 13. The semiconductor device 1 is mounted on the substrate M. This semiconductor device 1A is different from the semiconductor device 1 according to the first embodiment in that connection members 60 each including a plurality of connection electrodes 10 is further provided.

Each connection member 60 includes a plurality of connection electrodes 10, a substrate 61 in which the connection electrodes 10 are provided, terminal electrodes 62 (another terminal electrode) provided on the first surface side (upper side in the drawing) of the substrate 61, and a resin layer 63 (another resin layer) provided on the first surface side (upper side in the drawing) of the substrate 61 so as to cover the terminal electrodes 62. The connection member 60 may further include a fine wiring layer 64.

The substrate 61 is formed of silicon or the like similarly to the semiconductor substrates of the semiconductor dies 4 and 5. The substrate 61 may be formed of another material (for example, a resin or the like). Each connection electrode 10 is a through electrode penetrating the substrate 61, and its function is the same as that of the first embodiment. In the semiconductor device 1A according to the second embodiment, each connection member 60 may have a configuration similar to that of the semiconductor dies 4 and 5, and may have the fine wiring layer 64 between the resin layer 63 and the connection electrodes 10.

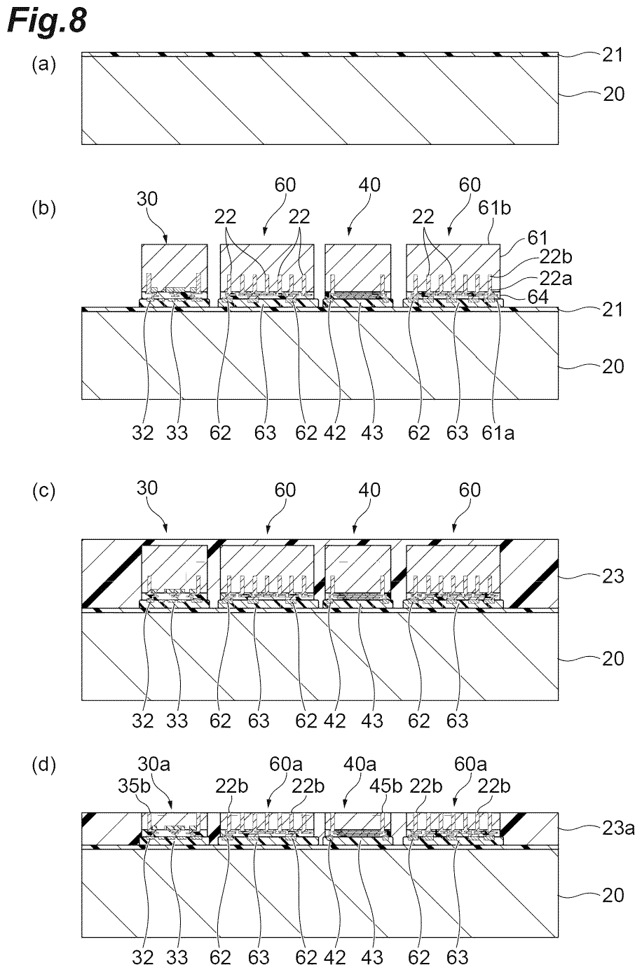

Next, an example of a method for manufacturing the semiconductor device 1A will be described with reference to FIGS. 8 to 11. FIGS. 8 to 11 are cross-sectional views sequentially illustrating the method for manufacturing the semiconductor device 1A.

In this method for manufacturing a semiconductor device, as illustrated in FIG. 8 (a), the temporary fixing layer 21 is formed on the carrier substrate 20 (first support).

Subsequently, as illustrated in FIG. 8 (b), each connection member 60 in which the plurality of posts 22 are provided inside the substrate 61 is prepared. The connection member 60 includes a plurality of posts 22, the substrate 61 having a first surface 61a and a second surface 61b on the opposite side, the terminal electrodes 62 provided on the first surface 61a side of the substrate 61, and the resin layer 63 provided on the first surface 61a side of the substrate 61 so as to cover the terminal electrodes 62. In the connection member 60, the second end 22b of each post 22 is located in the substrate 61, while the first end 22a of each post 22 is connected to the terminal electrode 62. The connection member 60 may further include the fine wiring layer 64 between the substrate 61 and the resin layer 63. The fine wiring layer 64 connects the posts 22 to the terminal electrodes 62. As the resin layer 63, the same material as those of the resin layers 33 and 43 of the semiconductor dies 30 and 40 can be used. The fine wiring layer 64 has a configuration corresponding to the fine wiring layers 34 and 44.

Subsequently, when the preparation of the connection member 60 is completed, the connection member 60 is attached to the carrier substrate 20 such that the lower surface on which the terminal electrodes 62 are provided faces the carrier substrate 20. At this time, the entire upper surface (second surface 61b) of the connection member 60 is vacuum-sucked by a collet to perform bonding. Each connection member 60 is moved to a predetermined position on the carrier substrate 20 by a collet sucked under vacuum, and is attached to the predetermined position on the carrier substrate 20 by the resin layer 63. At the time of attachment, since the terminal electrodes 62 of the connection member 60 is covered with the resin layer 63, the terminal electrodes 62 are protected. Furthermore, the semiconductor dies 30 and 40 are attached to the carrier substrate 20 simultaneously with the installation of the connection member 60 or before or after the installation of the connection member 60. A method of attaching the semiconductor dies 30 and 40 is similar to that of the first embodiment. As described above, a state illustrated in FIG. 8 (b) is obtained. In this step, the connection members 60 and the semiconductor dies 30 and 40 are arranged such that the terminal electrodes are in a face-down state facing downward.

Subsequently, when the attachment of the semiconductor dies 30 and 40 and the connection members 60 is completed, the resin layers 33, 43, and 63 each containing a curable resin composition are cured before the semiconductor dies 30 and 40 and the connection members 60 are encapsulated. The resin layers 33, 43, and 63 are cured using either one or both of heat and light. As a result, the semiconductor dies 30 and 40 and the connection members 60 are fixed to the carrier substrate 20.

Subsequently, as illustrated in FIG. 8 (c), an encapsulant layer 23 encapsulating the connection members 60 including the plurality of posts 22 and the semiconductor dies 30 and 40 with an encapsulant is formed on the carrier substrate 20. The encapsulant layer 23 is cured by heat or the like after encapsulating is performed. The resin layers 33, 43, and 63 may be further cured by the thermal curing.

Subsequently, when the encapsulant layer 23 is formed, the encapsulant layer is ground by CMP or the like, and as illustrated in FIG. 8 (d), the encapsulant layer is thinned to the ground encapsulant layer 23a. By this grinding, semiconductor dies 30a and 40a, in which the second ends 35b and 45b being the tips of the internal electrodes 35 and 45 become exposed to the outside of the encapsulant layer 23a, is formed. Furthermore, by this grinding, the second ends 22b of the plurality of posts 22 are also exposed to the outside of the encapsulant layer 23a.

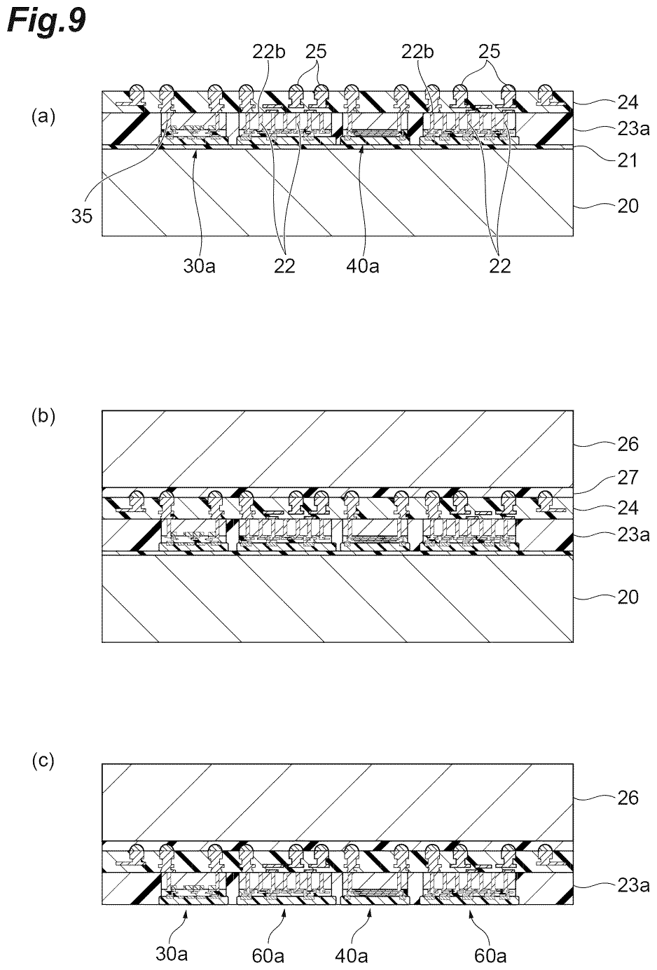

Subsequently, when the encapsulant layer 23a is formed, as illustrated in FIG. 9 (a), the wiring layer 24 is formed on the encapsulant layer 23a. The wiring portions 24a of the wiring layer 24 connect semiconductor dies 50 and 51 with an external device, and are connected to, for example, the second end 22b of each post 22 and the second ends 35b and 45b that are the tips of the internal electrodes 35 and 45 of the semiconductor dies 30a and 40a (see also FIG. 8 (d)). Furthermore, the connection bumps 25 may be formed on terminals on the opposite side (upper side in FIG. 9) of the wiring portions 24a.

Subsequently, when the wiring layer 24 is formed, as illustrated in FIG. 9 (b), the carrier substrate 26 is provided on the wiring layer 24. When the carrier substrate 26 is provided, a temporary fixing layer 27 may be provided on the wiring layer 24 side. Thereafter, as illustrated in FIG. 9 (c), the carrier substrate 20 is separated from the encapsulant layer 23a.

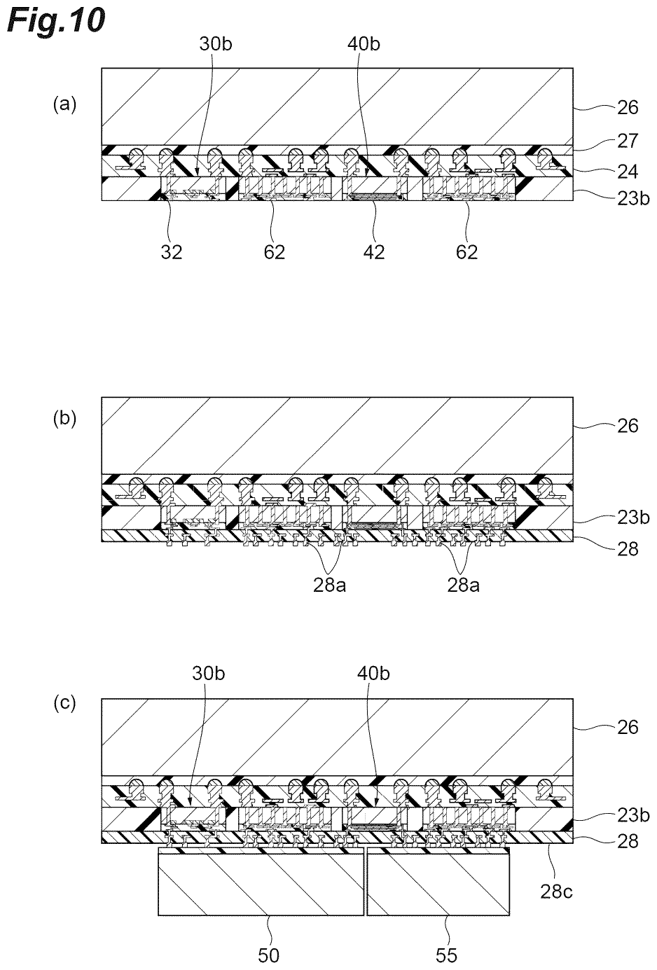

Subsequently, when the carrier substrate 20 is separated, the encapsulant layer 23a is ground by CMP or the like, and as illustrated in FIG. 10 (a), the encapsulant layer 23a is further thinned to the ground encapsulant layer 23b. In this grinding, grinding is performed until the terminal electrodes 32 and 42 provided in the resin layers 33 and 43 of the semiconductor dies 30 and 40 are exposed to the outside. Furthermore, grinding is performed until the terminal electrodes 62 provided in the resin layer 63 of each connection member 60a are exposed to the outside. The thickness of the ground resin layers 33, 43, and 63 may be 20 μm or more. When the encapsulant layer 23a is ground, the tip portions of the terminal electrodes 32 and 42 and the tip portions of the posts 22 may also be ground in the same manner.

Subsequently, when the grinding of the encapsulant layer is completed and the terminal electrodes 32, 42, and 62 are exposed to the outside, as illustrated in FIG. 10 (b), the wiring layer 28 electrically connected to the terminal electrodes 32, 42, and 62 is formed on the encapsulant layer 23b on which the resin layers 33, 43, and 63 have been ground. The wiring portions 28a of the wiring layer 28 connect the plurality of posts 22 and the semiconductor dies 30 and 40 to the semiconductor dies 50 and 55, and are connected to, for example, the first end 22a of each post 22, the terminal electrodes 32 and 42 of the semiconductor dies 30 and 40, and first ends 35a and 45a of the internal electrodes 35 and 45.

Subsequently, when the wiring layer 28 is formed, as illustrated in FIG. 10 (c), the semiconductor dies 50 and 55 are attached to a surface 28c (lower surface in the drawing) of the wiring layer 28 on a side opposite to the encapsulant layer 23b. In this step, the semiconductor die 50 and the semiconductor die 55 are electrically connected to each other by the embedded semiconductor die 40b. The embedded semiconductor die 30b is connected to the semiconductor die 50. Similarly, each post 22 is connected to the semiconductor dies 50 and 55 via the wiring layer 28.

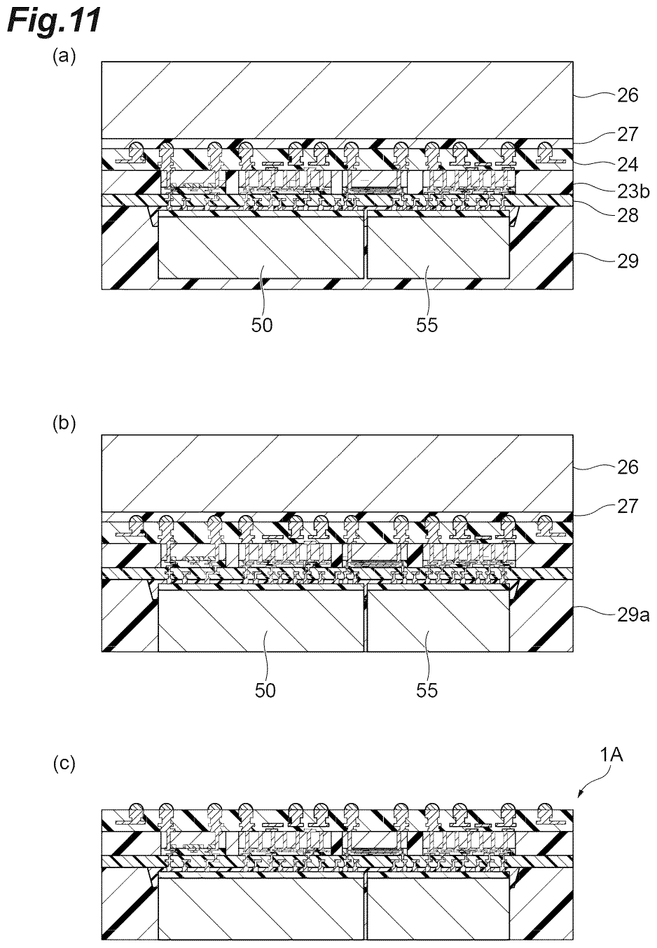

Subsequently, when the semiconductor dies 50 and 55 are mounted, as illustrated in FIG. 11 (a), the semiconductor dies 50 and 55 are encapsulated with an encapsulant on the wiring layer 28, and the encapsulant layer 29 is formed on the wiring layer 28. The encapsulant layer 29 is cured after encapsulating is performed. Thereafter, as illustrated in FIG. 11 (b), grinding may be performed until the surfaces of the semiconductor dies 50 and 55 are exposed from the surface of the encapsulant layer. As a result, the encapsulant layer 29 is thinned to the encapsulant layer 29a illustrated in FIG. 11 (b).

Subsequently, when the encapsulant layer 29a is ground, as illustrated in FIG. 11 (c), laser light irradiation or heat treatment is performed on the temporary fixing layer 27 to lower the adhesiveness of the temporary fixing layer 27 and separate the carrier substrate 26 from the wiring layer 24 by peeling. As a result, the connection bumps 25 are exposed to the outside. As described above, the semiconductor device 1A illustrated in FIG. 11(c) and 7 is manufactured. Such a semiconductor device 1A is mounted on the substrate M. At this time, an underfill material is applied between the semiconductor device 1 and the substrate M. Thereafter, the underfill material is cured by thermal curing or the like, thereby manufacturing the semiconductor device illustrated in FIG. 7.

As described above, in the method for manufacturing a semiconductor device according to the second embodiment, similarly to the first embodiment, the semiconductor dies 30 and 40 are attached to the carrier substrate 20 such that the first surfaces 31a and 41a provided with the terminal electrodes 32 and 42 face the carrier substrate 20. That is, the semiconductor dies 30 and 40 are attached in a face-down manner. Therefore, the semiconductor dies 30 and 40 can be reliably attached. Furthermore, in this method, each connection member 60 is attached to the carrier substrate 20 such that the first surface 61a provided with the terminal electrodes 62 faces the carrier substrate 20. That is, each connection member 60 is attached in a face-down manner. Therefore, each connection member 60 can be reliably attached.

Furthermore, in this method for manufacturing a semiconductor device, similarly to the first embodiment, the semiconductor dies 50 and 55 connected to the semiconductor dies 30 and 40 can be attached at the end of the process. Thereby, when a defect occurs at an intermediate stage, it is possible not to attach the semiconductor dies 50 and 55 which are expensive active dies. As a result, the overall manufacturing cost can be reduced.

Furthermore, in this method for manufacturing a semiconductor device, the posts 22 are provided not by individually forming the posts 22 on the carrier substrate 20, but by previously forming each connection member 60 each including the plurality of posts 22 and attaching each connection member 60 to the carrier substrate 20. Therefore, the formation of the posts 22 can be simplified. Furthermore, by forming the configuration and the material of each connection member 60 in the same manner as in the semiconductor dies 30 and 40 (excluding a circuit in the semiconductor die), the steps of picking up and attaching the semiconductor dies 30 and 40 and each connection member 60 can be simplified, and the manufacturing efficiency can be greatly enhanced.

Although the embodiment of the present disclosure has been described above, the present invention is not limited to the above-described embodiment, and modifications may be appropriately made without departing from the gist thereof.

### Reference Signs List

1, 1A semiconductor device
2, 3, 50, 55 semiconductor die (first semiconductor chip, second semiconductor chip)
4, 5, 30, 40 semiconductor die (semiconductor member)
4a, 5a, 32, 42 terminal electrode
6, 24 wiring layer (first wiring layer)
7, 28 wiring layer (second wiring layer)
8, 23, 23a, 23b encapsulant layer (first encapsulant layer)
9, 29, 29a encapsulant layer (second encapsulant layer)
10 connection electrode
11 connection bump
20 carrier substrate (first support)
22 post
22a first end
22b second end
23, 23a, 23b encapsulant layer (first encapsulant layer)
24 wiring layer (first wiring layer)
25 connection bump
26 carrier substrate (second support)
28 wiring layer (second wiring layer)
29, 29a encapsulant layer (second encapsulant layer)
30, 30a, 30b, 40, 40a, 40b semiconductor die (semiconductor member)
31, 41 semiconductor substrate
31a, 41a first surface
31b, 41b second surface
32, 42 terminal electrode
33, 43 resin layer
34, 44 fine wiring layer
35, 45 internal electrode
35a, 45a first end
35b, 45b second end
50, 55 semiconductor die (semiconductor chip)
60, 60a connection member
61 substrate
62 terminal electrode
63 resin layer
64 fine wiring layer

1. A method for manufacturing a semiconductor device, comprising:
providing a conductive post member having a first end and a second end on the opposite side on a first support, the first end being located on a side of the first support;
attaching a semiconductor member including a semiconductor substrate having a first surface and a second surface on the opposite side, a terminal electrode provided on the first surface side of the semiconductor substrate, and a resin layer provided on the first surface side so as to cover the terminal electrode, to the first support such that the first surface faces the first support;
curing the resin layer containing a curable resin composition after attaching the semiconductor member to the first support and before encapsulating the post member and semiconductor member;
forming a first encapsulant layer encapsulating the post member and the semiconductor member on the first support;
forming a first wiring layer electrically connected to at least the post member on the first encapsulant layer;
separating the first support from the first encapsulant layer;
grinding at least the resin layer so as to expose a tip of the terminal electrode; and
forming a second wiring layer electrically connected to at least one of the terminal electrode and the post member on the first encapsulant layer where the terminal electrode is exposed.

2. (canceled)

3. The method for manufacturing a semiconductor device according to claim 1,
wherein the resin layer when the semiconductor member is attached to the first support is a semi-cured or uncured curable resin composition.

4. The method for manufacturing a semiconductor device according to claim 1,
wherein the resin layer has a transmittance of 30% or more with respect to visible light.

5. The method for manufacturing a semiconductor device according to claim 1,
wherein in the attaching the semiconductor member, a position of the terminal electrode is determined through the resin layer, and the semiconductor member is attached to a predetermined position of the first support based on a result of the determination.

6. The method for manufacturing a semiconductor device according to claim 1,
wherein the resin layer contains inorganic fillers.

7. The method for manufacturing a semiconductor device according to claim 6,
wherein a content of the inorganic fillers is 30 mass % or more based on a total solid content contained in the resin layer.

8. The method for manufacturing a semiconductor device according to claim 6,
wherein an average particle diameter of the inorganic fillers is 20 μm or less.

9. The method for manufacturing a semiconductor device according to claim 1,
wherein an elastic modulus at 25° C. of the resin layer when being cured is 10 MPa or more.

10. The method for manufacturing a semiconductor device according to claim 1,
wherein the resin layer is formed by bonding a non-conductive adhesive film (NCF) or a die attach film (DAF).

11. The method for manufacturing a semiconductor device according to claim 1,
wherein a thickness of the resin layer is between 100% and 150% with respect to a height of the terminal electrode.

12. The method for manufacturing a semiconductor device according to claim 1,
wherein the resin layer is formed by bonding a resin film, and
a thickness of the resin film before bonding is between 75% to 150% with respect to the height of the terminal electrode.

13. The method for manufacturing a semiconductor device according to claim 1, further comprising,
grinding the first encapsulant layer such that the second end of the post member is exposed after forming the first encapsulant layer and before forming the first wiring layer.

14. The method for manufacturing a semiconductor device according to claim 1, further comprising
providing a second support on the first wiring layer after forming the first wiring layer,
wherein the first support is separated from the first encapsulant layer after providing the second support.

15. (canceled)

16. The method for manufacturing a semiconductor device according claim 1,
wherein the semiconductor member includes a fine wiring layer between the first surface of the semiconductor substrate and the terminal electrode.

17. The method for manufacturing a semiconductor device according to claim 1,
wherein the semiconductor member includes an internal electrode extending in a thickness direction of the semiconductor substrate,
wherein a first end of the internal electrode is connected to the second wiring layer via the terminal electrode, and a second end of the internal electrode is connected to the first wiring layer.

18. The method for manufacturing a semiconductor device according to claim 1, further comprising
attaching at least one semiconductor chip to a surface of the second wiring layer on a side opposite to the first encapsulant layer.

19. The method for manufacturing a semiconductor device according to claim 18,
wherein in the attaching a semiconductor chip, a first semiconductor chip and a second semiconductor chip as the at least one semiconductor chip are attached to the second wiring layer, and
wherein the first semiconductor chip and the second semiconductor chip are electrically connected by the semiconductor member.

20-21. (canceled)

22. The method for manufacturing a semiconductor device according to claim 1,
wherein the post member is provided in a substrate having a first surface and a second surface on the opposite side, and
wherein, in the providing a post member, the post member is provided on the first support by attaching a connection member to the first support such that the first surface faces the support, the connection member including the post member, the substrate, another terminal electrode provided on the first surface side of the substrate, and another resin layer provided on the first surface side of the substrate so as to cover another terminal electrode.

23. The method for manufacturing a semiconductor device according to claim 22,
wherein in the forming a first encapsulant layer, the connection member is encapsulated together with the semiconductor member,
wherein, in the grinding, the resin layer and another resin layer are ground such that another terminal electrode is exposed together with the terminal electrode, and
wherein, in the forming a second wiring layer, the second wiring layer is formed such that the second wiring layer is electrically connected to each of the terminal electrode and another terminal electrode.

24. The method for manufacturing a semiconductor device according to claim 22, further comprising
grinding a part of the semiconductor substrate and a part of the substrate together with the first encapsulant layer such that the second end of the post member is exposed after forming the first encapsulant layer and before forming the first wiring layer.

25-27. (canceled)
